(19) United States
(12) Patent Application Publication
(10) Pub. No.: US 2009/0033221 A1
(43) Pub. Date: Feb. 5, 2009

(54) Circuit board assembly and plasma display apparatus including the same

(76) Inventor: Sang-Young Lee, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 12/155,546

(22) Filed: Jun. 5, 2008

(30) Foreign Application Priority Data
Jul. 30, 2007 (KR) 2007-0076430

(51) Int. Cl. H01J 17/49; H05K 7/20

(52) U.S. Cl. 313/582; 361/721

(57) ABSTRACT

A circuit board assembly including: a circuit board; a plurality of circuit devices disposed on the circuit board; a plurality of heat sinks installed to contact with the circuit devices; and a support member connecting the adjacent heat sinks. The neighboring heat sinks have two facing surfaces, and the support member contacts at least a corner of one of the facing surfaces and at least a corner of the other one of the facing surfaces, so that the bending of the circuit board can be prevented.

### CLAIM OF PRIORITY

This application makes reference to, incorporates the same herein, and claims all benefits accruing under 35 U.S.C. §119 from an application for earlier filed in the Korean Intellectual Property Office on Jul. 30, 2007 and there duly assigned Serial No. 10-2007-0076430.

### BACKGROUND OF THE INVENTION

1. Field of the Invention

The present invention relates to a circuit board assembly and a plasma display apparatus including the circuit board assembly, and more particularly, to a circuit board assembly capable of preventing a circuit board from bending and a plasma display apparatus including the circuit board assembly.

2. Description of the Related Art

Plasma display apparatuses including plasma display panels are flat panel display apparatuses displaying images using a gas discharge, and have superior properties in terms of brightness, contrast, residual images, and viewing angle. In addition, plasma display apparatuses have large screens that are thin and light weight. Therefore, plasma display apparatuses are considered as the next generation of large flat panel display apparatuses.

In general, a plasma display apparatus includes a plasma display panel, a chassis base disposed in parallel with the plasma display panel, a circuit board mounted on a rear portion of the chassis base to drive the plasma display panel, and a case accommodating the plasma display panel, the chassis base, and the circuit board.

The circuit board is mounted onto the chassis base using a coupling unit, such as a bolt or a boss, such that there is a predetermined distance between the circuit board and the chassis base. A plurality of circuit devices is disposed on the circuit board. Each circuit device generates a lot of heat when the plasma display panel is driven, and thus, a heat sink is attached onto each circuit device in order to solve the heat generation problem. Thus, the heat sinks are disposed on the circuit board, and the circuit board may be bent due to the weight of the heat sinks. In particular, the circuit board can be easily bent based on a space between the heat sinks disposed on both sides of the circuit board. If the circuit board is thin, the bending occurs frequently.

When the circuit board is bent due to the weights of the heat sinks, the circuit board and circuit devices become disconnected, and thus, the plasma display panel fails to operate properly.

### SUMMARY OF THE INVENTION

The present invention provides a circuit board assembly that can easily prevent a circuit board from bending, and a plasma display apparatus including the circuit board assembly.

According to an aspect of the present invention, there is provided a circuit board assembly including: a circuit board; a plurality of circuit devices disposed on the circuit board; a plurality of heat sinks installed to contact with the circuit devices; and a support member connecting the adjacent heat sinks, wherein the neighboring heat sinks have facing surfaces, and the support member contact at least a corner of one of the facing surfaces and at least a corner of the other one of the facing surfaces.

The support member may include a recess formed on a side surface of the support member, so that side surfaces of the neighboring heat sinks are able to be inserted into the recess of the support member.

The recess of the support member may be formed in parallel with the circuit board.

The support member may be separated from the circuit board.

The support member may contact the circuit board.

The support member may be formed as a plate.

The heat sink may include at least one hole on an end portion, and the support member may include at least one boss for coupling to the hole of the heat sink.

A part on a lower center portion of the boss may be removed to facilitate detachable insertion to the hole of the heat sink.

The adjacent heat sinks may include a first heat sink and a second heat sink, the first heat sink may include a first recess on a portion facing the second heat sink, the second heat sink may include a first protrusion on a portion facing the first heat sink, and the support member may include a second recess and a second protrusion on both sides so that the second protrusion of the support member correspondingly couples to the first recess of the first heat sink and the second recess of the support member correspondingly couples to the first protrusion of the second heat sink.

The heat sinks each may contact with the circuit devices, respectively.

The support member may include a metal.

The support member may be an elastic member.

The support member may be formed of a material including an urethane resin, a polyurethane resin, an epoxy resin, or a synthetic rubber.

According to another aspect of the present invention, there is provided a plasma display apparatus including: a plasma display panel; a chassis base supporting the plasma display panel; a circuit board disposed on a rear portion of the chassis base; a plurality of circuit devices disposed on the circuit board and generating electric signals for driving the plasma display panel; a plurality of heat sinks installed to contact with the circuit devices; and a support member connecting the adjacent heat sinks, wherein the neighboring heat sinks have facing surfaces, and the support member contact at least a corner of one of the facing surfaces of the neighbouring heat sinks and at least a corner of the other one of the facing surfaces of the neighbouring heat sinks.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is an exploded perspective view of a circuit board assembly according to an embodiment of the present invention;

FIG. 2 is a side view of the circuit board assembly of FIG. 1, seen from a direction A;

FIG. 3 is a plan view of the circuit board assembly of FIG. 1, seen from a direction B;

FIG. 4 is a front view of the circuit board assembly of FIG. 1, seen from a direction C;

FIG. 5 is an exploded perspective view of a circuit board assembly according to another embodiment of the present invention;

FIG. 6 is a side view of the circuit board assembly of FIG. 5, seen from a direction D;

FIG. 7 is an exploded perspective view of a circuit board assembly according to another embodiment of the present invention;

FIG. 8 is a front view of the circuit board assembly of FIG. 7, seen from a direction E;

FIG. 9 is an exploded perspective view of a circuit board assembly according to another embodiment of the present invention;

FIG. 10 is a front view of the circuit board assembly of FIG. 9, seen from a direction F; and

FIG. 11 is an exploded perspective view of a plasma display apparatus including the circuit board assembly of FIG. 1, according to the embodiment of the present invention.

### DETAILED DESCRIPTION OF THE INVENTION

Structures and operations of a circuit board assembly and a plasma display apparatus according to embodiments of the present invention will be described with reference to accompanying drawings.

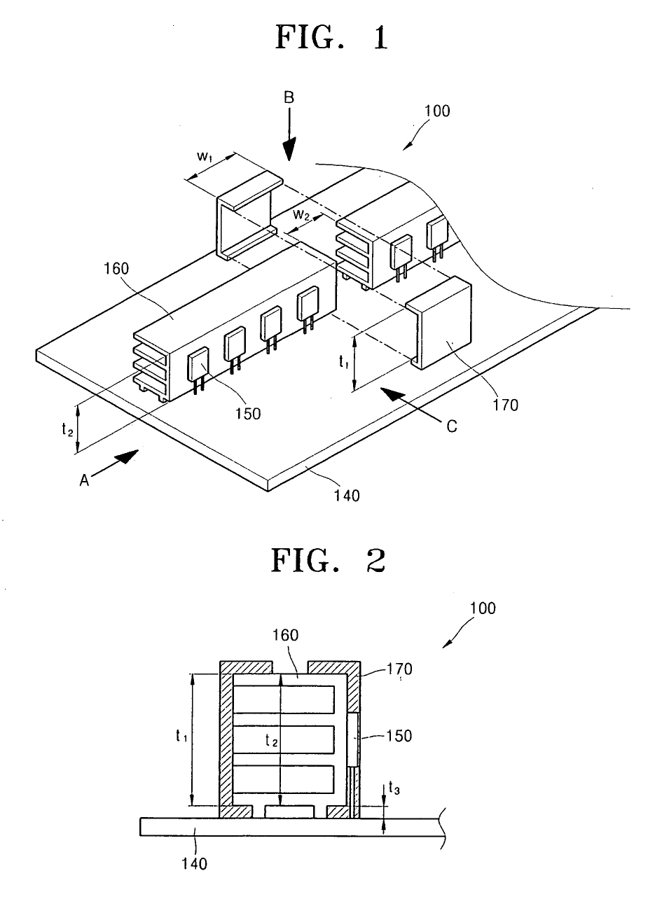

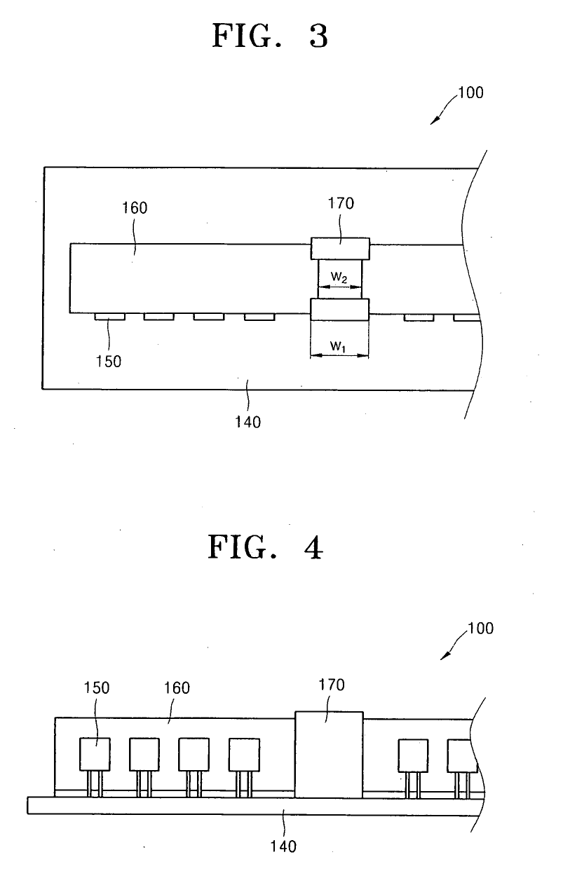

FIG. 1 is an exploded perspective view of a circuit board assembly 100 according to an embodiment of the present invention, FIG. 2 is a side view of the circuit board assembly 100 of FIG. 1, seen from a direction A, FIG. 3 is a plan view of the circuit board assembly 100 of FIG. 1, seen from a direction B, and FIG. 4 is a front view of the circuit board assembly 100 of FIG. 1, seen from a direction C.

The circuit board assembly 100 shown in FIGS. 1 through 4 includes a circuit board 140, circuit devices 150, heat sinks 160, and a support member 170.

The circuit devices 150 mounted on the circuit board 140 can be switching devices, field effect transistors (FETs), intelligent power modules (IPMs) having functions of the switching device or a device driving circuit, or diodes generating a lot of heat. However, the present invention is not limited thereto.

The heat sink 160 contacts a surface of each of the circuit devices 150 and is disposed on a top surface of the circuit board 140. The heat sink 160 includes a plurality of heat dissipation fins for discharging the heat of the circuit devices 150.

The support member 170 is disposed to connect neighboring heat sinks 160. The neighboring heat sinks have two facing surfaces therebetween, and thus, the support member 170 contacts at least a corner of one of the facing surfaces of the neighboring heat sinks 160, and at least a corner of the other one of the facing surfaces of the neighboring heat sinks 160. Therefore, the support member 170 can firmly connect the neighboring heat sinks 160. As the heat sinks 160 enlarge, the circuit board 140 may be bent due to the weights of the heat sinks 160. In particular, the circuit board 140 can be easily bent toward both directions of a separation space between the neighboring heat sinks 160. However, the support member 170 of the present embodiment connects the neighboring heat sinks 160, and thus, can prevent the circuit board 140 from bending. In particular, since the circuit devices 150 contact one of heat sinks 160, the sizes of the heat sinks 160 increase, and thus, the bending of the circuit board 140 worsens. However, the support member 170 can prevent the bending of the circuit board 140.

In more detail, the support member 170, according to the present embodiment, includes a recess on a side surface thereof. Referring to FIGS. 1 and 2, the side surface of the supporting member 170 includes a bent portion. A width (w1) of the support member 170 is wider than a width (w2) of the separation space between the heat sinks 160 so that the support member 170 can connect the neighboring heat sinks 160. The recess of the support member 170 is formed to have a predetermined height (t1). Referring to FIGS. 1 and 2, the height t1 of the recess in the support member 170 can be equal to a height (t2) of the heat sink 160. Referring to FIG. 2, an end portion of the support member 170 is inserted between the heat sink 160 and the top surface of the circuit board 140. Therefore, even when the circuit board assembly 100 is conveyed in a status where the heat sinks 160 are lifted during performing the processes, the support member 170 connects the heat sinks 160 that are separated from each other to prevent the circuit board 140 from bending. Although the lower end portion of the support member 170 contacts the top surface of circuit board 140 in FIG. 2, the present invention is not limited thereto, and thus, the lower end portion of the support member 170 can be separated apart from the top surface of the circuit board 140. That is, in this case, a thickness (t3) of the lower end portion of the support member 170 is reduced.

Referring to FIG. 3, two support members 170 are disposed on the neighboring heat sinks 160 to face each other so that the heat sinks 160 can be inserted in both sides of the two support members 170. The support member 170 can be disposed so that only a side of the heat sink 160 can be inserted into the support member 170, however, if the support members 170 are disposed on both sides of the heat sinks 160, the effect of preventing the bending of the circuit board 140 can be improved. Referring to FIG. 4, a front portion of the support member 170 has a rectangular shape. However, the shape of the support member 170 is not limited thereto, and thus, the support member 170 can be formed in various shapes as long as the support member 170 includes the recess, into which the side portion of the heat sink 160 is inserted, to support the heat sink 160.

The support member 170 can be formed of various materials. For example, the support member 170 can be formed of a metal, such as aluminum, however, the present invention is not limited thereto, and thus, the support member 170 may be formed of an elastic member. If the support member 170 is formed of a material including an urethane resin, a polyurethane resin, an epoxy resin, or a synthetic rubber to be elastic, the heat sinks 160 can be easily inserted into the support member 170. In addition, if an external shock is applied to the circuit board 140, the support member 170 can absorb, withstand the shock in order to prevent the circuit board 140 from bending.

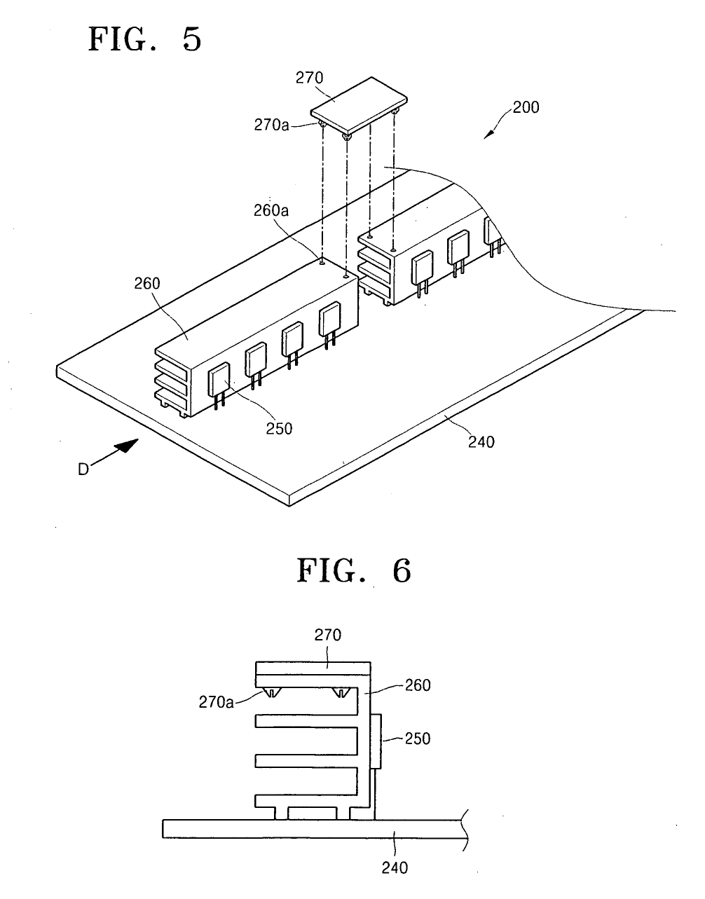

FIG. 5 is an exploded perspective view of a circuit board assembly 200 according to another embodiment of the present invention, and FIG. 6 is the side view of the circuit board assembly 200 seen from the direction D of FIG. 5. For the convenience of explanation, portions different from those of the previous embodiment will be described. Like reference numerals denote the like elements. The circuit board assembly 200 of the present embodiment includes a circuit board 240, circuit devices 250, heat sinks 260, and a support member 270. Thus, two adjacent heat sinks 260 can be connected to each other with the support member 270. The circuit board assembly 200 of the present embodiment is different from the circuit board assembly 100 of the previous embodiment with respect to the shape of the heat sink 260 and the support member 270.

The support member 270 is formed as a plate. Also, the support member 270 and the heat sinks 260 can be coupled to each other by using various coupling holes. Referring to FIGS. 5 and 6, the support member 270 includes bosses 270a, and the heat sink 260 includes holes 260a. The bosses 270a of the support member 270 are inserted into the coupling holes 260a of the heat sink 260, so that the support member 270 and the heat sink 260 can be coupled to each other. In order to attach/detach the support member 270 to/from the heat sink 260, a part of the center portion in the boss 270a of the support member 270 is removed. In addition, the boss 270a can be formed as a wedge, a width of which tapers toward the lower portion. Referring to FIGS. 5 and 6, the plate-shaped support member 270 is coupled to the neighboring heat sinks 260 using the bosses 270a, however, the present invention is not limited thereto. That is, the plate-shaped support member 270 can be coupled to the heat sinks 260 using various coupling units such as screws, pins, or rivets.

In the present embodiment, the support member 270 connects the neighboring heat sinks 260 to each other, and thus, even when the heat sinks 260 are elongated, the bending of the circuit board 240 can be easily prevented.

The circuit devices 250, and structures and materials of the heat sink 260 and the support member 270 have been described in the previous embodiment, and thus, detailed descriptions thereof is omitted.

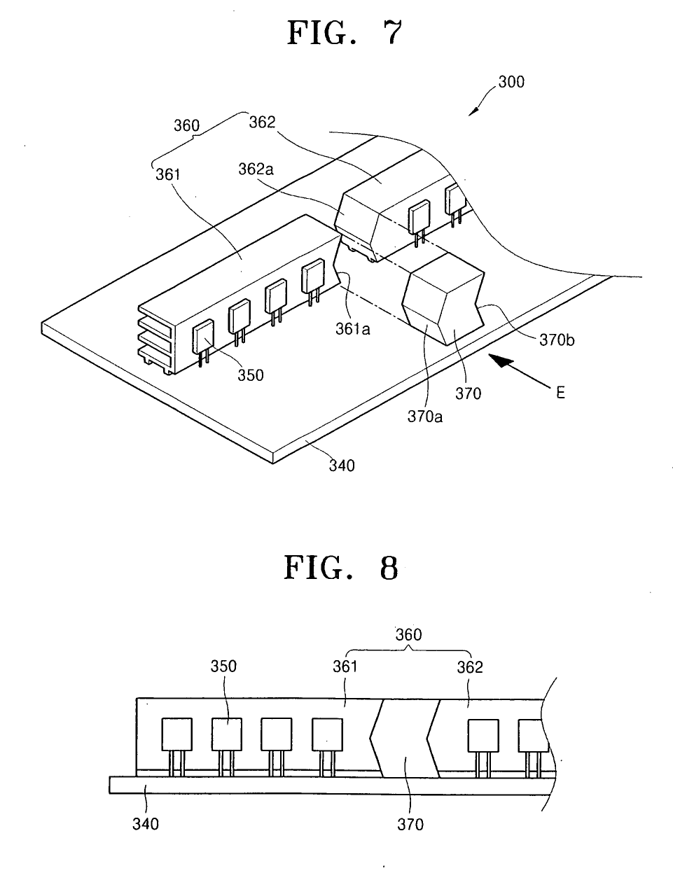

FIG. 7 is an exploded perspective view of a circuit board assembly 300 according to another embodiment of the present invention, and FIG. 8 is a front view of the circuit board assembly 300 seen from the direction E of FIG. 7. For convenience of explanation, portions different from the previous embodiment will be described. The circuit board assembly 300 of the present embodiment includes a circuit board 340, circuit devices 350, heat sinks 360, and a support member 370.

The heat sinks 360 are formed on the top surface of the circuit board 340, however, in the present embodiment, it is defined that two neighboring heat sinks 360 include a first heat sink 361 and a second heat sink 362 for convenience of explanation. The first heat sink 361 includes a first recess 361a, and the second heat sink 362 includes a protrusion 362a. The support member 370 connects the first heat sink 361 and the second heat sink 362 to each other. The support member 370 includes a second protrusion 370a that is correspondingly coupled to the first recess 361a of the first heat sink, and a second recess 370b that is correspondingly coupled to the first protrusion 362a of the second heat sink 362. Referring to FIG. 8, the support member 370 is disposed to correspondingly fit into the separation space between the first heat sink 361 and the second heat sink 362. The shapes of the first and second heat sinks 361 and 362 and the support member 370 are not limited thereto, that is, the first and second recesses 361a and 370b and the first and second protrusions 362a and 370a can be formed in various shapes that connect the neighboring heat sinks 360 to each other.

The support member 370 of the present embodiment also connects the neighboring heat sinks 360 to each other, and thus, even when the heat sinks 360 are elongated, the bending of the circuit board 340 can be easily prevented.

The circuit devices 350, and the structures and materials of the heat sink 360 and the support member 370 are the same as those of the previous embodiments, and thus, detailed descriptions thereof are omitted.

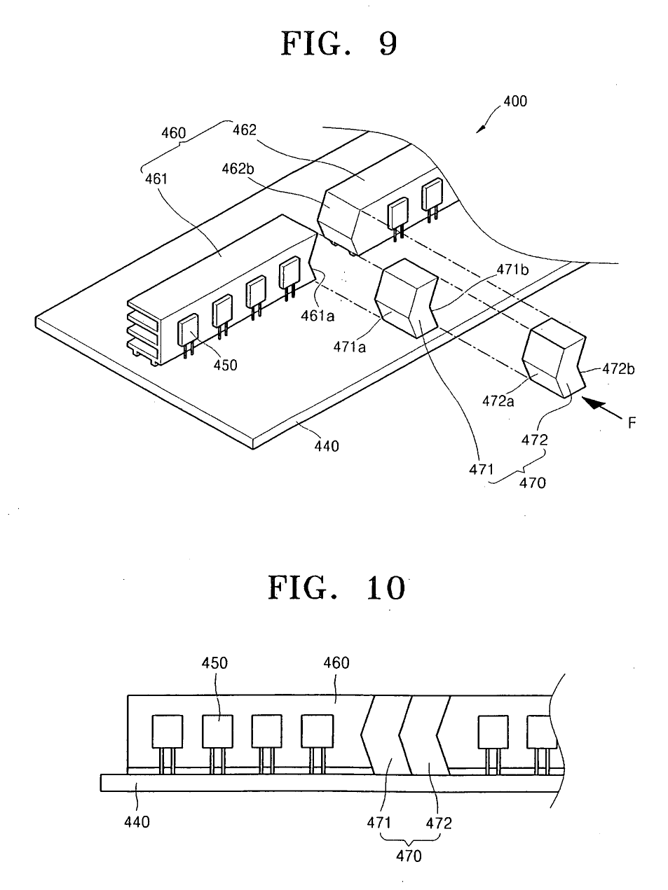

FIG. 9 is an exploded perspective view of a circuit board assembly 400 according to another embodiment of the present invention, and FIG. 10 is a front view of the circuit board assembly 400 seen from the direction F of FIG. 9.

For convenience of explanation, portions different from the previous embodiment will be described. The circuit board assembly 400 of the present embodiment includes a circuit board 440, circuit devices 450, heat sinks 460, and a support member 470.

The heat sinks 460 are formed on the top surface of the circuit board 440, however, in the present embodiment, for convenience of explanation, it is defined that two neighboring heat sinks 460 include a first heat sink 461 and a second heat sink 462. The first heat sink 461 includes a first recess 461a, and the second heat sink 462 includes a first protrusion 462b. The support member 470 includes a first support member 471 and a second support member 472. The first support member 471 includes a second protrusion 471a and a second recess 471b. The second support member 472 includes a third protrusion 472a and a third recess 472b. The second protrusion 471a of the first support member 471 is correspondingly coupled to the first recess 461a of the first heat sink 461, and the second recess 471b of the first support member 471 is correspondingly coupled to the third protrusion 472a of the second support member 472. The third recess 472b is coupled to a first protrusion 462b. Therefore, the support member 470 can connect the first heat sink 461 and the second heat sink 462 to each other. Referring to FIG. 9, the first support member 471 and the second support member 472 are disposed to correspondingly fit into the separation space between the first heat sink 461 and the second heat sink 462.

The support member 470 of the present embodiment also connects the heat sinks 460 to each other, and thus, even when the heat sinks 460 are elongated, the bending of the circuit board 440 such as the bending of the circuit board 440 can be easily prevented. In addition, the support member 470 also connects the heat sinks 460 to each other, and thus, even when the heat sinks 460 are elongated, the bending of the circuit board 440 such as the bending of the circuit board 440 can be easily prevented. In addition, the present invention is not limited to the present embodiment, and the number of support member can be increased. That is, the number of support member can be controlled to correspondingly fit into the separation space between the heat sinks. Therefore, an arrangement of the heat sinks can be freely designed.

The circuit devices 450, and structures and materials of the heat sinks 460 and the support member 470 are the same as those of the previous embodiments, and thus, detailed descriptions thereof are omitted.

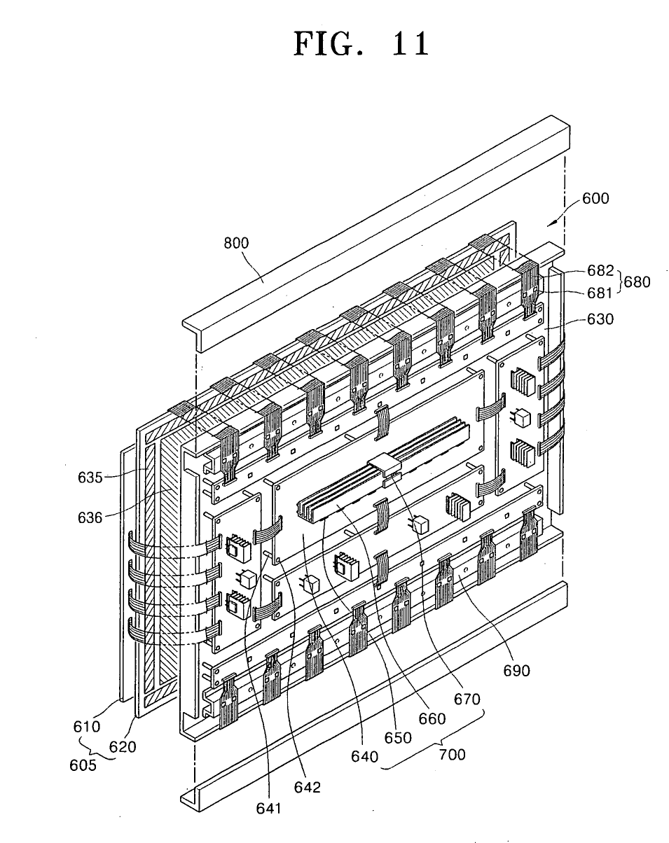

FIG. 11 is an exploded perspective view of a plasma display apparatus 600 including the circuit board assembly 100 of FIG. 1, according to the embodiment of the present invention. The plasma display apparatus 600 of the current embodiment includes the circuit board assembly 100 shown in FIG. 1, however, the present invention is not limited thereto. That is, although it is not shown in the drawings, the plasma display apparatus 600 can also include the circuit board assembly 200, 300, or 400 shown in FIGS. 5, 7, or 9.

The plasma display apparatus 600 of FIG. 11 includes a plasma display panel 605, a chassis base 630, a heat transfer medium 636, a circuit board 640, a circuit devices 650, heat sinks 660, a support member 670, and signal transmission units 680.

The plasma display panel 605 displays images and includes a front panel 610 and a rear panel 620 that face each other. On the front panel 610 and the rear panel 620, a plurality of electrodes, to which voltages are applied, are arranged, and the electrodes are covered by a dielectric layer. Barrier ribs, defining a plurality of discharge cells in which discharge occurs, are formed between the front panel 610 and the rear panel 620, and red, green, and blue phosphors are applied onto the barrier ribs. In addition, a discharge gas is filled in the discharge cells, and the discharge gas can be Xe gas. The chassis base 630 is disposed on a rear portion of the plasma display panel 605, and the chassis base 630 is coupled to the plasma display panel 605 using an adhesive member 635 such as a dual-adhesive tape.

The heat transfer medium 636, such as a heat transfer sheet, is inserted between the plasma display panel 605 and the chassis base 630. The heat transfer sheet 636 disperses the heat generated from the plasma display panel 605 to prevent the heat from concentrating locally, when the plasma display apparatus 600 operates. In addition, the heat transfer medium 636 transfers the heat generated from the plasma display panel 605 sufficiently to the chassis base 630, so that the heat can be discharged easily. A side of the heat transfer medium 636 contacts the plasma display panel 605, and can be divided into a plurality of pieces. The other side of the heat transfer medium 636 can be attached to the chassis base 630 for performing the heat dissipation efficiently or separated from the chassis base 630. The heat transfer medium 636 can be formed of a material having a high heat conductivity such as a graphite, a silicon glass, a silicon sheet, or an acrylic-based sheet.

The chassis base 630 supports the plasma display panel 605, and can be fabricated using a casting method or a pressing process. The chassis base 630 can be formed of a metal material having a high heat conductivity and a high stiffness such as aluminum, so that the heat transferred from the plasma display panel 605 can be dissipated to the outside efficiently and the stiffniess of the chassis base 630 can be maintained. However, the chassis base 630 can be formed of a material including a synthetic resin that has a light weight and a high stiffness. The chassis base 630 is formed as a flat plate.

A reinforcing member 690 can be installed on a rear surface of the chassis base 630 to prevent the chassis base 630 from bending or twisting, and can be formed of a material such as steel or aluminum.

The circuit board assembly 700 is disposed on a rear portion of the chassis base 630. The circuit board assembly 700 includes the circuit board 640, the circuit devices 650, the heat sinks 660, and the support member 670. The circuit board assembly 700 of FIG. 11 is the same as the circuit board assembly 100 shown in FIG. 1. The heat sinks 660 contact a surface of each of the circuit devices 650, and the support member 670 is disposed to connect the adjacent heat sinks 660 to each other. The support member 670 includes the recess formed in the side surface of the support member 670 so as to insert the heat sink 660 into the recess and connect the neighboring heat sinks 660. Therefore, even if an external shock is applied to the circuit board assembly 700, the bending of the circuit board 640 can be prevented. Consequently, the separation between the circuit devices 650 and the circuit board 640 can be prevented, and thus, an improper operation of the plasma display panel 605 can be prevented.

The chassis base 630 and the circuit board 640 are coupled to each other using bosses 641 formed on the chassis base 630 and into which screws 642 can be detachably inserted to couple the chassis base 630 and the circuit board 640. To do this, the bosses 641 may each include a screw recess into which the screw 642 can be detachably inserted.

The signal transmission units 680 that electrically connect the circuit board 640 to the plasma display panel 605 are disposed between the circuit board 640 and the plasma display panel 605. The signal transmission units 680 can each be a tape carrier package or a flexible printed cable.

The signal transmission units 680 each include an electronic device 681, such as integrated circuits that turn on/off the signal transmission from the circuit devices 650 to the plasma display panel 605, and a wiring portion 682 formed as a tape.

A cover plate 800 can be disposed on a rear surface of the chassis base 630 so as to cover the signal transmission units 680. The cover plate 800 discharges the heat generated by the signal transmission units 680 sufficiently to the outside, and prevents the signal transmission units 680 from being damaged. The cover plate 800 can be formed of a material including metal.

According to a circuit board assembly of the present invention, the bending of a circuit board can be easily prevented by using a support member.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A circuit board assembly comprising:
a circuit board;
a plurality of circuit devices disposed on the circuit board;
a plurality of heat sinks installed to contact with the circuit devices; and
a support member connecting the adjacent heat sinks,
wherein the neighboring heat sinks have facing surfaces, and the support member contact at least a corner of one of the facing surfaces and at least a corner of the other one of the facing surfaces.

2. The circuit board assembly of claim 1, wherein the support member includes a recess formed on a side surface of the support member, so that side surfaces of the neighboring heat sinks are able to be inserted into the recess of the support member.

3. The circuit board assembly of claim 2, wherein the recess of the support member is formed in parallel with the circuit board.

4. The circuit board assembly of claim 1, wherein the support member is separated from the circuit board.

5. The circuit board assembly of claim 1, wherein the support member contacts the circuit board.

6. The circuit board assembly of claim 1, wherein the support member is formed as a plate.

7. The circuit board assembly of claim 6, wherein the heat sink includes at least one hole on an end portion, and the support member includes at least one boss for coupling to the hole of the heat sink.

8. The circuit board assembly of claim 7, wherein a part on a lower center portion of the boss is removed to facilitate detachable insertion to the hole of the heat sink.

9. The circuit board assembly of claim 1, wherein the adjacent heat sinks include a first heat sink and a second heat sink, the first heat sink includes a first recess on a portion facing the second heat sink, the second heat sink includes a first protrusion on a portion facing the first heat sink, and the support member includes a second recess and a second protrusion on both sides so that the second protrusion of the support member correspondingly couples to the first recess of the first heat sink and the second recess of the support member correspondingly couples to the first protrusion of the second heat sink.

10. The circuit board assembly of claim 1, wherein the heat sinks each contact with the circuit devices, respectively.

11. The circuit board assembly of claim 1, wherein the support member includes a metal.

12. The circuit board assembly of claim 1, wherein the support member is an elastic member.

13. The circuit board assembly of claim 12, wherein the support member is formed of a material including an urethane resin, a polyurethane resin, an epoxy resin, or a synthetic rubber.

14. A plasma display apparatus comprising:
a plasma display panel;
a chassis base supporting the plasma display panel;
a circuit board disposed on a rear portion of the chassis base;
a plurality of circuit devices disposed on the circuit board and generating electric signals for driving the plasma display panel;
a plurality of heat sinks installed to contact with the circuit devices; and
a support member connecting the adjacent heat sinks,
wherein the neighboring heat sinks have facing surfaces, and the support member contact at least a corner of one of the facing surfaces of the neighbouring heat sinks and at least a corner of the other one of the facing surfaces of the neighbouring heat sinks.
